(19) United States
(12) Patent Application Publication
(10) Pub. No.: US 2002/0140073 A1
(43) Pub. Date: Oct. 3, 2002

(54) Multichip module

(75) Inventors: Tsung Ming Pai, Tainan (TW); Sung Fei Wang, Kaohsiung (TW)

Correspondence Address: LOWE HAUPTMAN GOPSTEIN GILMAN & BERNER, LLP, Suite 310, 1700 Diagonal Road, Alexandria, VA, 22314, US

(73) Assignee: Advanced Semiconductor Engineering, Inc.

(21) Appl. No.: 09/818,622

(22) Filed: Mar. 28, 2001

(51) Int. Cl. H01L 23/02

(52) U.S. Cl. 257/686; 257/724; 257/777

(57) ABSTRACT

A multichip module mainly comprises two chips disposed on a substrate in a stacking arrangement. The multichip module is characterized by having a dummy chip interposed between the two semiconductor chips. The dimension of the dummy chip is smaller than the lower semiconductor chip such that no portion of the dummy chip interferes with a vertical line of sight of each bonding pad of the lower semiconductor chip to permit wire bonding thereof. Furthermore, the dummy chip has a predetermined thickness sufficient to provide clearance between the two chips for keeping the upper chip from damaging the bonding wires coupled to the lower chip.

### BACKGROUND OF THE INVENTION

1. Field of the Invention

This invention relates to a multichip module (MCM), and more specifically to a multichip module having a stacked chip arrangement.

2. Description of the Related Art

As electronic devices have become more smaller and thinner, the packages for protecting and interconnecting IC chips have the same trend, too.

With ever increasing demands for miniaturization and higher operating speeds, multi-chip modules (MCMs) are increasingly attractive in a variety of electronics. MCMs which contain more than one die can help minimize the system operational speed restrictions imposed by long printed circuit board connection traces by combining, for example, the processor, memory, and associated logic into a single package. In addition, MCMs decrease the interconnection length between IC chips thereby reducing signal delays and access times.

The most common MCM is the “side-by-side” MCM. In this version two or more IC chips are mounted next to each other (or side by side each other) on the principal mounting surface of a common substrate. Interconnections among the chips and conductive traces on the substrate are commonly made via wire bonding. The side-by-side MCM, however, suffers from a disadvantage that the package efficiency is very low since the area of the common substrate increases with an increase in the number of semiconductor chips mounted thereon.

Therefore, U.S. Pat. No. 5,323,060 teaches a multichip stacked device (see FIG. 1) comprising a first semiconductor chip 11 attached to a substrate 12 and a second semiconductor chip 13 stacked atop the first semiconductor chip 11. The chips 11, 13 are respectively wire bonded to the substrate 12. U.S. Pat. No. 5,323,060 is characterized by using an adhesive layer 14 between the two chips 11, 13 to provide clearance between the chips for the loops of the bonding wires. The wire bonding process of the underlying chip 11 must be completed before the chip 13 can be stacked on the chip 11. This means that the die bonding process must be repeated for each additional layer of the stack. In addition to adding extra process steps, there is a chance of damaging the underlying wires. Additionally, the clearances between two adjacent chips in the stack are quite tight. This will lead to limited processing window in wire binding process, thereby creating reliability problems of the bonding wires.

Typically, the normal loop height of bonding wires is generally about 10 to 15 mils. As thinner packages have been developed, the loop height has been reduced with conventional bonding techniques down to about 6 mils in height by changes in the loop parameters, profile and wire types. However, this loop height is considered to be a minimum obtainable loop height as the loop height less than 6 mils will cause wire damage and poor wire pull strength. Therefore, using this conventional bonding technique, the adhesive layer 14 must have a thickness greater than 6 mils to prevent the bonding wires 15 from contacting the chip 13. Typical materials for the adhesive layer 14 include epoxy and tape. However, it is very difficult to form an epoxy layer with a stable bond line thickness above 6 mils. Once the bond line thickness is not stable, it will introduce unsatisfactory coplanarity of the upper chip 13, after mounting of the upper chip 13. Sometimes the bond line thickness is so uneven to cause the chip 13 to come in contact with the lower bonding wires thereby resulting in deformation or shift of the loop profile of the lower bonding wires. Further, even using a tape with a thickness of 6 mils, it will increase the cost of the final product, and the reliability of resulted package will suffer from the CTE mismatch between the thermoplastic tape and the silicon chip.

### SUMMARY OF THE INVENTION

Accordingly, it is a primary object of the present invention to provide a multichip module characterized by having a dummy chip interposed between an upper chip and a lower chip wherein the two chips are disposed on a chip carrier in a stacking arrangement and respectively wire bonded to the chip carrier. The dummy chip has a predetermined thickness sufficient to provide clearance between the two chips for lower bonding wires coupled to the lower chip thereby keeping the upper chip from damaging the lower bonding wires.

According to a preferred embodiment of the present invention, the multichip module mainly comprises two chips disposed on a substrate in a stacking arrangement. The multichip module is characterized by having a dummy chip interposed between the two semiconductor chips. The dimension of the dummy chip is smaller than the lower semiconductor chip such that no portion of the dummy chip interferes with a vertical line of sight of each bonding pad of the lower semiconductor chip to permit wire bonding thereof.

In the multichip module according to a preferred embodiment of the present invention, the dummy chip help to provide clearance between the two chips for keeping the upper chip from damaging the bonding wires coupled to the lower chip.

### BRIEF DESCRIPTION OF THE DRAWINGS

Other objects, advantages, and novel features of the invention will become more apparent from the following detailed description when taken in conjunction with the accompanying drawings.

FIG. 1 is a cross-sectional view of a conventional multichip module; and

FIG. 2 is a cross-sectional view of a multichip module according to a preferred embodiment of the present invention.

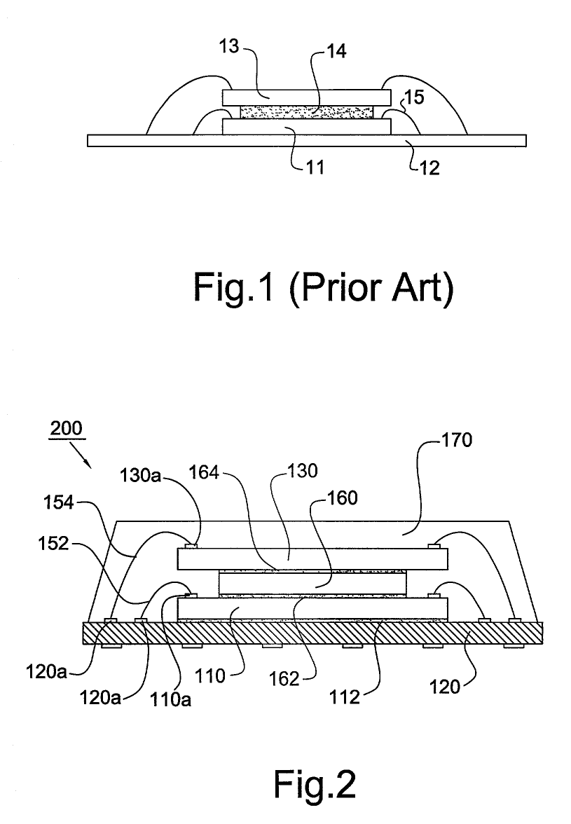

### DETAILED DESCRIPTION OF THE PREFERRED EMBODIMENTS

FIG. 2 shows a multichip module 200 according to a preferred embodiment of the present invention. The multichip module 200 mainly comprises two semiconductor chips 110, 130 stacked each other and mounted to a substrate 120. The substrate 120 is provided with a structure for making external electrical connection comprising a plurality of conductive traces 120a. Each of the semiconductor chips 110, 130 has a plurality of bonding pads (denoted with the numeral 110a, 130a respectively in FIG. 2) formed on the active surface thereof for access to its inner circuits. The bonding pads 110a, 130a are electrically connected to the conductive traces 120a through a plurality of bonding wires 152, 154 respectively. The multichip module 200 is preferably provided with a package body 170 encapsulating the chips 110, 130 and the bonding wires 152, 154 against a portion of the substrate 120. The package body 170 is formed over the chips 110, 130 and a portion of the substrate 120 using known plastic molding methods such as transfer molding.

The substrate 120 may be formed from a core layer made of fiberglass reinforced BT (bismaleimide-triazine) resin or FR-4 fiberglass reinforced epoxy resin. Alternatively, the substrate 230 may be a film substrate or a ceramic substrate. It should be understood that the substrate 120 may be replaced by a lead frame. Typically, the lead frame comprises a plurality of conductive leads having inner lead portions and outer lead portions wherein the inner lead portions thereof are adapted to be electrically connected to semiconductor chips and the outer lead portions thereof are used for making electrical connection to outside.

Referring to FIG. 2, the multichip module 200 is characterized by having a dummy chip 160 interposed between the two semiconductor chips 110, 130. It is noted that the dummy chip 160 of the present invention has the same material as the semiconductor chips mounted on the substrate. That means the dummy chip 160 and the silicon chips have a consensus CTE (coefficient of thermal expansion) thereby greatly enhancing the reliability of finished package. Furthermore, wiring is not required for the dummy chip because it is not employed in the device operation.

The dummy chip 160 in accordance with the present invention has a dimension smaller than the lower semiconductor chip 110 such that no portion of the dummy chip 160 interferes with a vertical line of sight of each bonding pad 110a of the chip 110 to permit wire bonding thereof. It is preferable to reserve a distance of at least 6 mils between the dummy chip 160 and the bonding pads 110a of the chip 110, thereby providing a larger processing window during wire bonding, and thereby enhancing the reliability of bonding wires 152 for the underlying chip 110.

The dummy chip 160 is interposed between the chips 110, 130 by means of two adhesive layers 162, 164. The types of suitable adhesive include epoxy, thermoplastic materials, tape, etc. Typically, the normal loop height of bonding wires 152 is generally about 10 to 15 mils. Through changing in the loop parameters, profile and wire types, the loop profile may be reduced with conventional bonding techniques down to about 4-6 mils in height. Therefore, using conventional bonding technique, the dummy chip 160 and the adhesive layers 162, 164 must have a thickness greater than 6 mils to prevent the chip 130 from contacting the loop profile of bonding wires 152. Preferably, the adhesive layers 162, 164 are controlled to have a bond line thickness of about 1 mil; hence, the dummy chip 160 must have a thickness of at least 4 mils to provide clearance between the two chips for keeping the upper chip from damaging the bonding wires for the lower chip. In addition, the dummy chip interposed between the two chips helps to provide a good thickness control such that the semiconductor chip 130 is mounted with satisfactory coplanarity thereby enhancing the reliability of the multichip module 200.

Although the invention has been explained in relation to its preferred embodiment, it is to be understood that many other possible modifications and variations can be made without departing from the spirit and scope of the invention as hereinafter claimed.

what is claimed is:

1. A multichip module comprising:
a chip carrier being provided with a structure for making external electrical connection;
a first semiconductor chip attached to the chip carrier, the first semiconductor chip having a plurality of first bonding pads formed on the active surface thereof;
a plurality of first bonding wires electrically coupling the first bonding pads to the structure for making external electrical connection;
a dummy chip attached to the active surface of the first semiconductor chip; and
a second semiconductor attached onto the dummy chip and electrically coupled to the structure for making external electrical connection,
wherein the dummy chip has a predetermined thickness sufficient to provide clearance between the first and second chips for the first bonding wires, and the dummy chip has a coefficient of thermal expansion (CTE) substantially the same as the CTE of the semiconductor chips.

2. The multichip module as claimed in claim 1, wherein the first semiconductor chip and the second semiconductor chip substantially have the same size.

3. The multichip module as claimed in claim 1, wherein the chip carrier is a substrate.

4. The multichip module as claimed in claim 1, wherein the chip carrier is a lead frame.

5. The multichip module as claimed in claim 1, wherein the dummy chip is attached to the first semiconductor chip in a manner that no portion of the dummy chip interferes with a vertical line of sight of each first bonding pad of the first semiconductor chip to permit wire bonding thereof
